(19) United States
(12) Patent Application Publication
(10) Pub. No.: US 2007/0224522 A1
(43) Pub. Date: Sep. 27, 2007

(54) Substrate including deformed portions and method of adjusting a curvature of a substrate

(76) Inventors: Myoung-soo Lee, Suwon-si (KR); Dong-wan Kim, Seongnam-si (KR); Sung-min Huh, Yongin-si (KR); Suk-jong Bae, Seoul (KR)

Correspondence Address: LEE & MORSE, P.C., 3141 FAIRVIEW PARK DRIVE, SUITE 500, FALLS CHURCH, VA, 22042, US

(21) Appl. No.: 11/723,280

(22) Filed: Mar. 19, 2007

(30) Foreign Application Priority Data
Mar. 21, 2006 (KR) 10-2006-0025812

(51) Int. Cl. H01L 31/0232; B32B 9/00; B32B 17/06; G21K 5/00; G03F 1/00; B32B 17/10

(52) U.S. Cl. 430/5; 428/428; 428/430; 378/35; 257/435

(57) ABSTRACT

Adjusting a curvature of a substrate includes forming at least one deformed portion in a predetermined region of a substrate, wherein the substrate includes a curved region before forming the at least one deformed portion, and forming the at least one deformed portion includes irradiating the substrate in the predetermined region so as to fixedly displace substrate material in the predetermined region.

### BACKGROUND OF THE INVENTION

1. Field of the Invention

The present invention relates to a substrate including deformed portions and a method of adjusting a curvature of a substrate. More particularly, the present invention relates to a substrate including deformed portions and a method of adjusting a curvature of the substrate suitable for flattening the substrate.

2. Description of the Related Art

A photomask may include patterns that may be transferred to a substrate, such a silicon wafer, during a photolithography process used to manufacture semiconductor devices. In some manufacturing processes, the formation of fine patterns on a substrate may depend heavily on photomasks. Accordingly, the quality of the photomask may significantly affect the formation of patterns during the photolithography process.

The quality of the photomask may be evaluated according to various factors and by various methods. Such factors and methods may include, e.g., fineness of a pattern, uniformity of the width of pattern lines, uniformity in shape, cleanliness of surfaces or regions where light is transmitted or reflected, light absorbing ability in regions where light is received, surface flatness of the photomask, etc. Among these factors, the surface flatness of the photomask may be an important factor that affects the adjustment of directions and focus positions of light that is transmitted or reflected.

In particular, as the pattern to be formed becomes smaller, the surface flatness of the photomask may become critical. Accordingly, surface flatness of the photomask may determine the ability to achieve sub-micron line widths in a manufacturing process. In the case of a transmissive photomask, when the surface of the photomask is not flat, light passing through a transmissive region of the photomask may not travel straight, light that is diffracted may not maintain a predetermined angle of diffraction, etc. As such, patterns formed on the substrate may be asymmetrically formed, not formed at all, etc.

In the case of a reflective photomask, e.g., a reflective photomask configured for extreme ultraviolet (EUV) light, the surface flatness of the photomask may significantly affect the formation of patterns. Since light is incident or reflected in the reflective photomask at a predetermined angle, e.g., about 6°, the flatness may affect the formation of patterns more than in the case of a transmissive photomask. Further, the reflective photomask generally uses light of smaller wavelengths and has finer patterns. Therefore, the surface flatness may be more important than other photomask characteristics.

If photomask substrates were initially flat, adjusting the curvature of the photomask, e.g., to flatten the photomask, might not be important. However, such substrates may not be sufficiently flat. That is, the difference between the highest and the lowest points on the surface of the photomask may exceed, e.g., 50 nm, even for a very high quality photomask. Moreover, when photomask patterns are formed on a photomask substrate that exceeds the above-described height range, the flatness of the photomask may further deteriorate. Accordingly, a photomask substrate having a height difference in excess of 50 nm may be not adequate for forming fine patterns in a photolithography process, and thus may not be suitable for practical applications. Thus, there is a need to overcome such a deficiencies in the conventional art, in view of the time and cost required to manufacture a photomask. In particular, if the flatness of a substrate or a surface flatness of a completed photomask can be corrected, it may be possible to improve productivity and reduce manufacturing costs.

### SUMMARY OF THE INVENTION

The present invention is therefore directed to a substrate including deformed portions and a method of adjusting a curvature of a substrate, which substantially overcome one or more of the problems due to the limitations and disadvantages of the related art.

It is therefore a feature of an embodiment of the present invention to provide a substrate having a pattern of deformed portions below the surface, the deformed portions adjusting a curvature of the substrate, such that the substrate may have a flatness suitable for use as, e.g., a photomask.

It is therefore another feature of an embodiment of the present invention to provide a method of adjusting a curvature of a substrate that includes forming at least one deformed portion in a predetermined region of the substrate so as to displace substrate material, which may be effective in flattening a surface of the substrate.

At least one of the above and other features and advantages of the present invention may be realized by providing a substrate including a pattern of deformed portions below a surface of the substrate, wherein the pattern includes at least a first row of deformed portions that extends in a direction substantially parallel to the surface of the substrate.

The substrate may include a quartz layer. The substrate may further include a second row of deformed portions below the first row, such that the first row may be disposed between the surface and the second row. The first row may be disposed above a midline of the substrate, the midline being parallel to the surface and half way between the surface and an opposing surface.

The substrate may be a photomask substrate having a lithographic pattern at the surface. The lithographic pattern may include a reflective layer.

The deformed portions may be expanded portions. The expanded portions may be portions of substrate material having a density lower than that of adjacent unexpanded substrate material. The expanded portions may be oblong with a longer dimension oriented in a direction substantially normal to the surface and a shorter dimension oriented in the direction substantially parallel to the surface. The expanded portions may have an average size of greater than or equal to about 1 μm, the size being determined in the direction substantially parallel to the surface. The deformed portions in the first row may have a pitch of greater than or equal to about 1 μm.

At least one of the above and other features and advantages of the present invention may also be realized by providing a method of adjusting a curvature of a substrate, including forming at least one deformed portion in a predetermined region of a substrate, wherein the substrate includes a curved region before forming the at least one deformed portion, and forming the at least one deformed portion includes irradiating the substrate in the predetermined region so as to fixedly displace substrate material in the predetermined region.

Forming the at least one deformed portion may increase a flatness of a surface of the curved region. A first surface of the substrate may have a photomask pattern, and the curved region may be at the first surface. The method may further include mapping the substrate to determine the curvature of the substrate, wherein the mapping may include measuring a surface curvature of the photomask pattern.

Irradiating the substrate may include irradiation with a laser. The irradiation may be performed with a pulse time of less than or equal to about 1 ms. The irradiation may be performed with a pulse energy of less than or equal to about 10 mJ. The at least one deformed portion may be formed in a focus location of the laser. Displacing the substrate material may include expanding the substrate material.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a schematic view of a photomask according to an embodiment of the present invention;

FIGS. 2A and 2B illustrate schematic cross-sectional views of cases in which a concave or convex curvature of a substrate is adjusted according to an embodiment of the present invention;

FIGS. 3A and 3B illustrate schematic cross-sectional views of cases in which a surface of a substrate is flattened according to an embodiment of the present invention;

FIG. 4 illustrates a schematic representation of an irradiation energy applied to a substrate according to an embodiment of the present invention;

FIG. 5 illustrates a schematic view of irradiation of a substrate to form an expanded portion therein according to an embodiment of the present invention; and

FIG. 6 illustrates a flowchart of an implementation of a method of adjusting a curvature of a substrate according to an embodiment of the present invention.

### DETAILED DESCRIPTION OF THE INVENTION

Korean Patent Application No. 10-2006-0025812, filed on Mar. 21, 2006, in the Korean Intellectual Property Office, and entitled: “Photomask Including Expanded Portion in Substrate and Method of Planarizing Surface of Photomask,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, or one or more intervening layers may be present. In addition, it will also be understood that when a layer is referred to as being “between” two layers, it can be the only layer between the two layers, or one or more intervening layers may also be present. Additionally, the accompanying figures may depict relative positions among elements, but are not limited to such positions. For example, where a photomask is illustrated as being used while the surface on which patterns are formed is facing downward, it may also be used while the surface on which patterns are formed is facing upward. Therefore, expressions such as “on” and “upper” are to be understood as being relative terms. Additionally, the present invention will be described with reference to idealized views in which embodiments of the invention are shown. It will be understood that the depictions of features in these views are not intended to limit the scope of the present invention, and are to include variations such as those that may result from manufacturing techniques and/or tolerances. Thus, regions shown in the drawings are illustrated in schematic form and the shapes of the regions are presented simply by way of illustration and not as a limitation. Like reference numerals refer to like elements throughout.

Hereinafter, embodiments of the present invention may be described with reference to particular implementations wherein a curvature of a photomask substrate is flattened. However, it will be appreciated that the present invention may be used to adjust curvature in other fashions, and is not limited in application to a photomask, but may be generally applied to any suitable substrate. Further, embodiments of the present invention may be described with reference to particular implementations wherein the photomask is a reflective photomask. However, it will be appreciated that other photomasks, e.g., transmissive photomasks, may be used, and embodiments of the present invention may be similarly applied to other substrates, e.g., mirrors, optical elements, chip-on-glass (COG) devices, semiconductor wafers, etc. Additionally, embodiments of the present invention may be described with reference to particular implementations wherein substrate material is deformed and displaced using a laser to increase a volume of the substrate material. However, it will be appreciated that other sources of irradiation or energy may be employed.

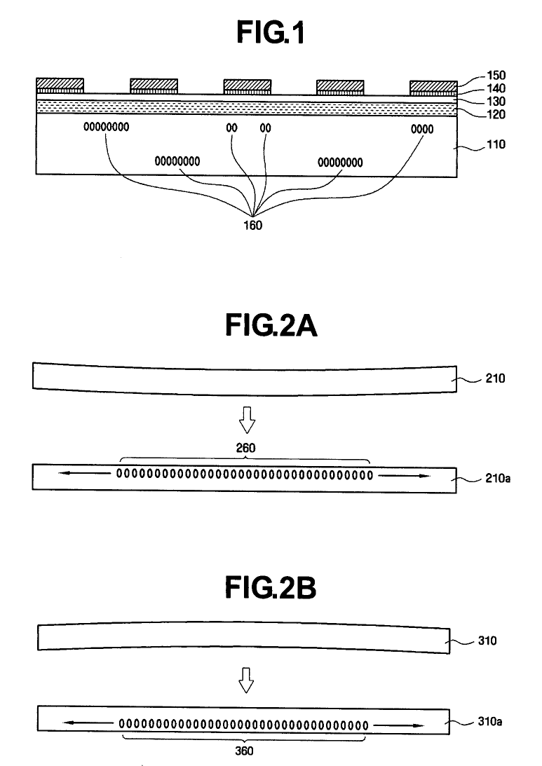

FIG. 1 illustrates a schematic view of a photomask according to an embodiment of the present invention. The photomask may be, e.g., a substrate used for transferring a pattern to a semiconductor wafer on which a photosensitive film is formed using light, i.e., a reticle. The photomask may be a reflective photomask used in an EUV photolithography process, in which light having a very short wavelength, e.g., about 13.4 nm, is used. Referring to FIG. 1, a photomask according to an embodiment of the present invention may include a substrate 110 having a photomask pattern at a first surface. In detail, the photomask may include the substrate 110 having one or more deformed portions in which substrate material has been displaced. In an implementation, the deformed portions may be expanded portions 160. The expanded portions 160 may have relatively low densities with respect to adjacent, undeformed material.

The substrate 110 may include a glass layer such as quartz. In an implementation, the substrate 110 may be a glass substrate having a square shape, with a side length of about 6 inches and a thickness of about 250 mil (inch/1000). The substrate 110 may further have one or more of a reflective layer 120, a capping layer 130, a buffer pattern 140 and a light absorbing pattern 150. The capping layer 130 may be disposed on the reflective layer 120, the buffer pattern 140 may be disposed on the capping layer 130, and the light absorbing pattern 150 may be disposed on the buffer pattern 140.

The reflective layer 120 may be, e.g., a laminated structure having a plurality of material layers. In an implementation, a pair of layers including a first material layer and a second material layer may be repeatedly laminated to form the reflective layer 120. Further, a third material layer may be interposed between the first and second material layers. The first material layer may include, e.g., a molybdenum, and the second material layer may include, e.g., silicon. The material layers may be alternately laminated, e.g., by laminating the first material layer and the second material layer alternately, although they need not be laminated in a regular order. The reflective layer 120 may not completely reflect the light at the surface, but instead may reflect light at interfaces of the material layers. The thickness of laminated material layers may be set so that light components reflected by each interface of material layers undergo interference with each other. That is, layer thicknesses may be determined in consideration of the refractive index of each material layer.

For example, a thickness of about 2.7 nm may be the thickness of about 11 atomic layers of molybdenum, and a thickness of about 4.1 nm may be the thickness of about 15 atomic layers of silicon. Light components used in a total thickness of about 6.8 nm may be reflected and may interfere with each other. In addition, each material layer may be further laminated by the above-described thickness. The thickness of each layer may have an error of, e.g., less than about 25%. When two light components are reflected at the interface between two material layers, they may interfere with each other when they have phase difference in the range of about ¼ to about ¾. Therefore, even if the thickness has an error of less than about ¼, interference may occur.

Each material layer may be formed by a sputtering method, a deposition method, etc. For example, in the case of the deposition method, a CVD (Chemical Vapor Deposition) method, a PVD (Physical Vapor Deposition) method, an ALD (Atomic Layered Deposition) method, etc., may be performed. The thickness of total reflective layers may be determined so as to stably reflect light. For example, a laminated structure of about 20 pairs may result in stable reflection, although 40 pairs may be laminated for a more stable result. Of course, the laminated structure may be formed to be thinner or thicker according to the requirements of the particular system.

The third material layer may be interposed between the first and second material layers, and may be, e.g., boron carbon (B₄C). A material layer may be further interposed therebetween to improve interference, to enhance the adhesive force of other layers, etc. The third material layer may have a smaller thickness than the first and second material layers. For example, the third material layer may have a thickness of less than about 1 nm.

The light absorbing pattern 150 may absorb, rather than reflect, light that is incident on the surface of the photomask. Thus, where the light absorbing pattern 150 is disposed between the light source and the reflective layer 120, the light absorbing pattern 150 may prevent light from being incident on the reflective layer 120 in predetermined regions thereof. The light absorbing layer 150 may be formed of, e.g., one or more of a metal, including chrome (Cr), molybdenum (Mo), aluminum (Al), tantalum (Ta), etc., a metal compound including chrome oxides (CrₓO_{y}), chrome nitrides (CrₓN_{y}), tantalum nitrides (TaₓN_{y}), tantalum boron nitrides (TaₓB_{y}N_{z}), etc., a metal alloy, another inorganic material, etc. A thinner light absorbing pattern 150 may enable the formation of a more delicate pattern. However, if the thickness of the light absorbing pattern 150 is too thin, it may be difficult to control a manufacturing process. Further, defects such as pin holes may be more likely. The thickness of the light absorbing pattern 150 may be about 50 nm to about several hundreds of nm, for example, about 70 nm to about 90 nm.

When the light absorbing pattern 150 is formed, the capping layer 130 may protect the reflective layer 120 from damage like etching or other physical impact. If the light absorbing pattern 150 has defects, the reflective layer 120 may still be protected in ongoing processes, such as a process for correcting or repairing the light absorbing pattern 150 and a process for cleaning the photomask. Further, the capping layer 130 may be applied to improve an adhesive force between the reflective layer 120 and the light absorbing pattern 150. The reflective layer 120 may be formed of, e.g., inorganic materials such as silicon or silicon oxides, of refractory metal such as ruthenium, titanium, tantalum, etc., of metal compounds like chrome nitrides, etc. The reflective layer 120 may have a thickness smaller than a wavelength of the light to be used. The thickness of the reflective layer 120 may be about 11 nm.

The buffer pattern 140 may be applied to improve an adhesive force between the reflective layer 120 or the capping layer 130 and the light absorbing pattern 150, and may be formed of one or more of the materials used for the capping layer 130, or of materials different from those of the capping layer 130. The capping layer 130 and/or the buffer pattern 140 may be omitted. That is, the capping layer 130 may function as the buffer pattern 140, or the buffer pattern 140 may be formed without the capping layer 130.

Referring again to FIG. 1, one or more expanded portions 160 may be formed in the substrate 110 using, e.g., laser irradiation. When a laser is irradiated in the substrate 110 formed of a quartz material, an atomic bonding state of a portion of the substrate 110 on which the laser is focused may be changed. More specifically, the substrate 110 having a general atomic bonding state may gain energy from the laser and, thus, be excited so that interatomic bonding is deformed and/or density is lowered. For example, irradiation may change the atomic bonding state to an amorphous bonding state that increases a volume of the substrate material in the irradiated region with respect to an adjacent, non-irradiated region.

According to an embodiment of the present invention, the density and volume of the expanded portion 160 may be adjusted by laser irradiation. If a volume of a region that is occupied by a number of the expanded portions 160 is increased, stress may be generated inside the substrate 110. The generated stress may partially or entirely affect the curvature of the substrate 110. In an implementation, one or more expanded portions 160 may be formed by deforming portions of the substrate in one or more predetermined regions in order to affect a surface curvature of the substrate 110, e.g., so as to flatten the surface of the substrate 110.

A single expanded portion 160 may generate stress three-dimensionally in the substrate, while if a plurality of expanded portions 160 is formed in a one-dimensional direction, stress may be predominantly applied corresponding to the one-dimensional direction. If the expanded portions 160 are formed two-dimensionally, stress may be predominantly applied two-dimensionally. Accordingly, by forming the expanded portions 160 in predetermined regions of the substrate 110, the expanded portions 160 may be variously distributed so as to flatten the substrate 110.

The expanded portions 160 may be expanded by a factor of about 1.001 with respect to adjacent unexpanded substrate material, which may be effective to adjust the curvature of the substrate 110 while maintaining a stable bonding state of the substrate 110.

In an implementation, the expanded portions 160 may be about 1.5 μm from the surface of the substrate 110, although this may of course be adjusted depending on the particular system.

FIGS. 2A and 2B illustrate schematic cross-sectional views of cases in which a concave or convex curvature of a substrate is adjusted according to an embodiment of the present invention. Referring to FIGS. 2A and 2B, components other than the substrate are omitted in order to convey a clear understanding of the present invention. Therefore, only a substrate 210 is illustrated.

Referring to FIG. 2A, a substrate 210 may have an initial concave curvature. It will be appreciated that the terms “concave” and “convex” are relative terms, and are not intended to limit the scope of the present invention. Rather, such terms are used to concisely convey an understanding of the structure of the substrate 210. For convenience, both “concave” and “convex,” as these terms relate to the illustrations, are determined from above the substrate 210. Thus, the substrate 210 illustrated in FIG. 2A will be referred to as “concave” and the substrate referred to in FIG. 2B will be referred to as “convex.”

Referring to FIG. 2A, the curvature of the concave region of the substrate 210 may be adjusted, e.g., to flatten or reduce the concavity, by forming a plurality of stress generating deformed portions, which may be expanded portions 260. More specifically, if the expanded portions 260 generate stress in the vicinity of an upper concave surface of the substrate 210, stress may be generated in a horizontal direction, as indicated by the lateral solid arrows in FIG. 2A. Accordingly, the plurality of expanded portions 260 may bend the substrate 210 in a direction opposite to its initial curvature, so that the substrate 210 is flattened.

In another implementation that will be described in additional detail below, the expanded portions 260 may increase the volume of the substrate 210 locally such that the substrate 210 expands in a vertical direction. Accordingly, curvatures of localized regions of the substrate 210 may be adjusted. Thus, embodiments of the present invention may be applied to adjust a curvature of the substrate 210 as whole and/or in localized regions.

As described above, the stress generating expanded portions 260 may be formed adjacent to the upper surface of the substrate 210, e.g., above the midline or in the top half in the width direction of the substrate 210, such that stress may be generated to cause the substrate 210 to bend in an upward direction, thereby offsetting the initial concave shape and flattening the substrate 210.

Referring to FIG. 2B, in another embodiment, a substrate 310 that is initially bent in a convex shape may have the curvature adjusted so as to flatten the convexity. More specifically, if expanded or stress generating portions 360 are formed adjacent to a lower surface of the substrate 310, stress may be generated in a horizontal direction, as indicated by the laterally extending solid arrows, so that the curvature of the substrate 310 is adjusted to reduce or eliminate the convex shape, i.e., to flatten the substrate 310. Again, the volume of the substrate 310 may also be expanded in the vertical direction so as to locally flatten regions of the substrate 310, as will be described below. When the expanded portions 360 are formed closer to the lower surface of the substrate 210, that is, formed so as to be located in a bottom half in the width direction of the substrate 310, stress may be generated to cause the substrate 310 to bend upward, thereby flattening the initial convex shape. Therefore, the substrate 310 that was initially bent in a convex shape may be flattened.

Regions where the expanded portions 360 are formed may differ according to the particular structure of the substrate 310. To apply stress in an upward direction of the substrate 310, i.e., to reduce or eliminate an initial concavity, the expanded portions 360 may be formed closer to an upper concave surface of the substrate 310. To apply stress in a downward direction of the substrate 310, i.e., to reduce or eliminate an initial convexity, the expanded portions 360 may be formed closer to the lower concave surface of the substrate 310.

FIGS. 2A and 2B illustrate cases in which expanded portions 260 and 360 are respectively formed in a monolayer structure. However, embodiments of the present invention may also be applied to a multilayer structure, which may also result in a more stable structure. A laser may be irradiated in predetermined regions of the substrates 210 and 310 so as to form the respective expanded portions 260 and 360, such that density is lowered and volume is expanded in the expanded portions 260 and 360 with respect to adjacent, undeformed substrate material. Thus, stress may be selectively generated in the substrates 210 and 310 to adjust the curvature thereof, both locally and across the substrates 210 and 310.

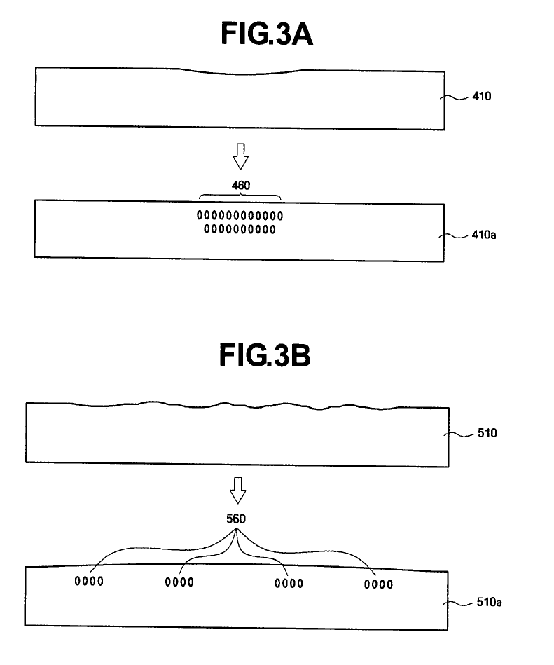

FIGS. 3A and 3B illustrate schematic cross-sectional views of cases in which a surface of a substrate is flattened according to an embodiment of the present invention. In particular, FIG. 3A illustrates a schematic longitudinal cross-sectional view of a substrate 410, e.g., a glass substrate, in a case in which a curvature of an initially concave surface of the substrate 410 is adjusted so as to locally flatten the substrate 410. Referring to FIG. 3A, according to this embodiment of the present invention, the surface of the substrate 410 may be flattened by forming expanded portions 460 inside the substrate 410. The expanded portions 460 may be formed as multiple layers in the substrate, i.e., as a series of rows, arrays, planes, etc., located at various depths in the substrate 410.

In another implementation (not shown), the curvature of the surface of the substrate 410 may be adjusted by adjusting the size and/or shape of the unit expanded portions 460. More specifically, if a unit expanded portion 460 is formed with a larger size in the vertical direction than the expanded portions 260 and 360 shown in FIGS. 2A and 2B, a vertical stress may become larger and may thereby increase the flattening effect on the surface of the substrate 410.

As illustrated in FIG. 3A, the substrate 410 may not be curved entirely, but may be locally curved. The local curvature may be adjusted such that the locally curved region is flattened. The expanded portions 460 may be formed as oblong or oval shapes having a height that is greater than a width and/or in multiple layers, which may be advantageous as compared to the case in which the plurality of expanded portions is formed in a single layer, as shown in FIGS. 2A and 2B. That is, whereas it may be desirable to primarily generate a horizontal stress in the cases shown in FIGS. 2A and 2B, it may be desirable to primarily generate a vertical stress in the case shown in FIG. 3A. Although not shown, the expanded portions 460 of FIG. 3A may have different shapes from those of the expanded portions 260 and 360 shown in FIGS. 2A and 2B. For example, the expanded portions 460 may be formed longer in the vertical direction than the expanded portions 260 and 360. Additionally, the expanded portions 460 may be formed in multiple layers or planes, e.g., two or more layers or planes.

FIG. 3B illustrates a schematic cross-sectional view of a substrate 510 in which a surface of the substrate 510 having both concave and convex portions is flattened. Referring to FIG. 3B, according to this embodiment of the present invention, the surface of the substrate 510 may be flattened by forming expanded portions 560 inside the substrate 510 having localized concave and convex regions. Expanded portions 560 formed in regions of the substrate 510 whose surfaces are concave may generate a vertical stress, caused by a volume increase of the substrate 510, so as to adjust the concave surfaces to make them even with the convex regions. As illustrated, the flattened surface may be slightly expanded, as the previously concave surface may rise due to the stress of the expanded portion 560. It will be appreciated that the surface of the substrate 510 before flattening has been exaggerated for convenience of illustration.

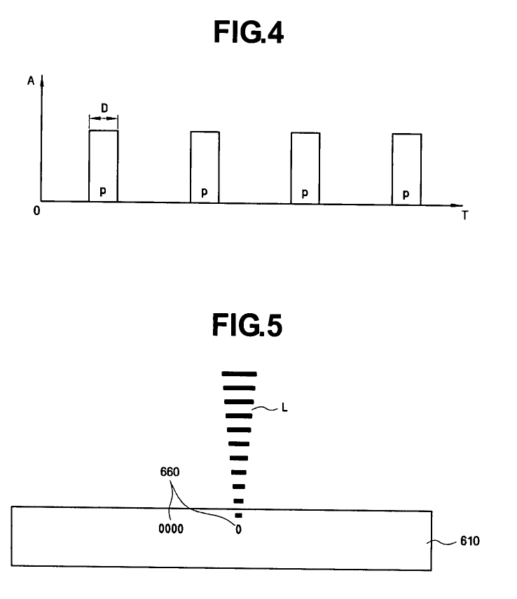

FIG. 4 illustrates a schematic representation of an irradiation energy applied to a substrate according to an embodiment of the present invention. Referring to FIG. 4, the X axis represents time T, and the Y axis represents amplitude A of a laser. In an embodiment of the present invention, the substrate may be deformed using laser irradiation. The laser may be operated in a pulsed mode, in which a pulsed laser having a pulse energy in the range of several mJ to hundreds of mJ may be repeatedly irradiated on the substrate for periods of duration D, which may be on the order of lower than milliseconds. The laser may be pulsed using, e.g., a shutter, etc. The laser may be an ultrashort pulsed laser having very short pulse duration D.

The laser may have a very short pulse duration D, over which significant heat transfer or thermal diffusion does not occur in the substrate. In particular, portions of the substrate on which laser is irradiated may transfer heat to the vicinities thereof, in which case, chemical bond breaking or substrate deformation may occur across a relatively large region. However, as most solid materials have a thermal diffusion coefficient that is below several millimeters per second, the thermal diffusion over a unit length of one micrometer may require several milliseconds per micrometer. Therefore, if the laser is irradiated for a sufficiently short duration, heat transfer or thermal diffusion may be limited and it may thus be possible to change the bonding state of only the portion on which the laser is irradiated. Accordingly, the laser may be irradiated for a time lower than milliseconds, and the chemical bond breaking or deformation of the substrate may be localized. In an implementation, the substrate may be a glass substrate and the laser may be irradiated on the substrate using a laser pulse duration D of about several nanoseconds (1×10⁻⁹) or less for more effectiveness.

As a duration time D of a pulse P may be short, a radiating time may also be short. Further, the size of the deformed portion may be small. If the radiating time is too long, undue chemical bond breaking in the substrate material may occur. Therefore, shorter irradiation times may be desirable. In other words, microseconds may be preferable to milliseconds, nanoseconds may be preferable to microseconds, picoseconds may be preferable to nanoseconds, femtoseconds may be preferable to nanoseconds, etc. It will be appreciated that various methods may be employed to control the energy delivered to the substrate. For example, the energy of the laser pulse may be on the order of microjoules (μJ) per pulse, the duration D may be adjusted, a focus of a laser pulse P may be adjusted, etc.

In an implementation, irradiation may be performed using laser pulse P having a duration D of about a femtosecond (1×10⁻¹⁵ second). In detail, a solid femtosecond laser having Ti:Sapphire laser or fiber laser as a base may be used, although a laser having another base may also be used. The femtosecond laser may have a very high peak power, e.g., in the range of terrawatt (1×10¹²) to petawatt (1×10¹⁵), although it may be inconvenient if the energy is too high. The, energy per one pulse P may on the order of mJ or less, and power output may be on the order of about 0.5 watt to about 2 watts, e.g., an average output of about 1 watt. The duration D may be about 120 femtoseconds or less, and the wavelength of laser may be about 800 nm. The laser may be pulsed with a frequency of, e.g., about 100 KHz, i.e., a pitch between the duration D may be on the order of tens of microseconds (1×10⁻⁶).

FIG. 5 illustrates a schematic view of irradiation of a substrate to form an expanded portion therein according to an embodiment of the present invention. Referring to FIG. 5, expanded portions 660 may be formed by irradiating a laser L on a region where the expanded portions 660 are to be formed in a substrate 610. The laser L may be irradiated using a predetermined focus, which may be changed while the substrate 660 is being irradiated.

Various process variables may be adjusted in forming one unit expanded portion 660. Adjustment may be made by using amplitude, duration and frequency of a pulse. These process variables may be adjusted according to the size and shape, i.e., the three-dimensional volume including height, width, etc., of the expanded portions 660 to be formed. It will be appreciated that such adjustments to the process variables may be highly specific to the particular system, and thus the particular process variable values set forth above are merely exemplary and are not intended to limit the scope of the present invention.

In an implementation, the pulse frequency of the laser L may be set to about 100 KHz. In this regard, the frequency means the number of times that a laser pulse exists per one second. One pulse may form one unit expanded portion 660, and a unit expanded portion 660 may be formed with an average width in the range of about 1 to about 2 μm. Therefore, the time that is required for forming one unit expanded portion may be about 1×10⁻⁵ second, and, ignoring other factors, about 1×10⁵ unit expanded portions 660 may be formed per second. The laser L may be irradiated using a beam having a size in the range of tens to hundreds of μm, which may be focused on a region where the expanded portions 660 are to be formed. In this case, the expanded portions 660 may be located within about 0.5 μm to 1 μm radius from the focus location. More delicate and/or more uniform expanded portions 660 may be obtained by lowering the pulse frequency or duration D of the laser L, or by adjusting peak power or average energy.

Where the present invention is implemented is to correct surface flatness of the substrate 610, the height of the expanded portions 660 may be more significant than the width of the expanded portions 660. In this respect, in the present embodiment, the expanded portions 600 may have an average height of over tens of μm, e.g., an average height of about 25 μm. In other cases, the expanded portions may be formed with an average height of over hundreds of μm. The intervals between the respective expanded portions 660 may be set to an average pitch of about 5 μm.

It may be preferable to predetermine the size and interval of the expanded portions 660 in order to obtain optimal effects. Further, it may be preferable to form the expanded portions with a small size at dense intervals to correct the bending of the substrate 610. However, adjusting the size of the expanded portions 660 may be more significant than adjusting intervals between the expanded portions 660 when adjusting the curvature of the surface of the substrate 610.

The expanded portions 660 may be formed in various shapes and with various sizes according to the irradiation of the laser L. An expanded portion 660 may be large, although the expanded portion 660 that may be formed during one pulse of the laser L may be very small. The size of the expanded portions 660 that are generated by accumulated laser L may reach up to hundreds of μm.

One unit expanded portion 660 may be a deformed portion of the substrate in which the density is lowered and volume is expanded, as compared to the substrate material in that region before the laser L is irradiated thereon. The exact amount of change in the density and or volume may not be readily determined, and it is estimated that the density and/or volume differences are quite small. The size of the deformed portions and the degree of expansion of the unit volume of the deformed portions may not be constant, and thus it may be difficult to accurately determine these changes. It is estimated, however, that these changes may be on the order of 1.001×, although it will be appreciated that this estimate is not intended to limit the scope of the present invention.

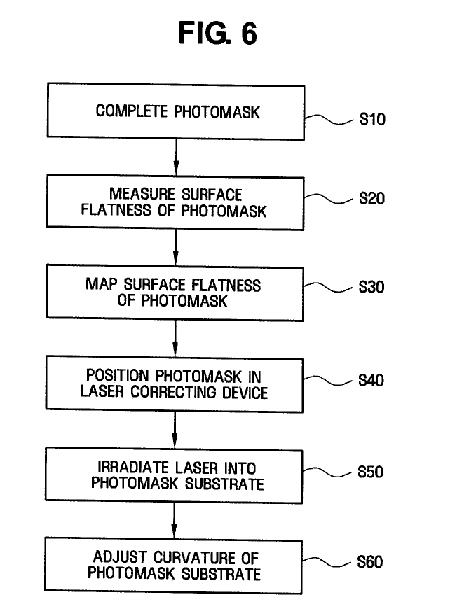

FIG. 6 illustrates a flowchart of an implementation of a method of adjusting a curvature of a substrate according to an embodiment of the present invention. Referring to FIG. 6, formation of the photomask may be completed by a general method (S10). Next, surface flatness of the substrate of the completed photomask may be measured (S20). The surface flatness of the substrate of the photomask may be measured by using flatness measuring equipment such as an alpha stepper, etc. Next, regions where surfaces are not flat may be mapped (S30). The regions may be automatically mapped by the measuring equipment and then converted into three-dimensional graphic data, coordinates of regions whose surfaces are not flat may be recorded for mapping, etc. A step of measuring the surface of the photomask may be performed while a step of mapping is performed. Next, the photomask may be positioned in a laser correcting device, and then the focus of the laser may be positioned on the regions that are scanned and mapped (S40). Next, the laser may be irradiated such that the focus thereof is positioned in the substrate, thereby forming an expanded portion (S50). When the laser is irradiated into the substrate, the laser may be irradiated on a surface where patterns are not formed. Next, the photomask may be withdrawn from the laser correcting device and may undergo a cleaning process, etc., thereby completing formation of a photomask having a flattened surface (S60).

It will be appreciated that embodiments of the present invention may be applied to a reflective photomask in order to adjust a curvature of a surface of a reflective layer. That is, the surface of the reflective layer may be flattened by mapping a region in which the surface of the reflective layer is not flat, and forming expanded portions inside the substrate in locations corresponding to the nonflat surface. Of course, other substrates besides transmissive and reflective photomasks may also be flattened. In addition, the present invention may be applied to a substrate made of materials other than glass. For example, the method may be applied to a silicon substrate. The silicon substrate may have a low transparency to laser irradiation, which may limit the formation of expanded portions to regions near the surface of the silicon substrate. Of course, other means of deforming the substrate may also be employed.

The present invention may be applied not only to the case in which expanded portions are formed, but also to the case in which bonding of substances forming the substrate is partially changed. That is, when laser is irradiated on a material layer having stable bonding, the bonding state may be partially changed. Thus, the present invention may be applied to the case when it is required to weaken a bonding force of substances, or to apply further conductivity for impurity doping, or to form a polycrystalline structure.

As described above, the photomask whose surface is flattened according to an embodiment of the present invention may be used to transfer fine patterns onto a wafer, thereby enhancing the capabilities of the photolithography process and improving manufacturing productivity. Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A substrate, comprising:
a pattern of deformed portions below a surface of the substrate, wherein the pattern comprises at least a first row of deformed portions that extends in a direction substantially parallel to the surface of the substrate.

2. The substrate as claimed in claim 1, wherein the substrate comprises a quartz layer.

3. The substrate as claimed in claim 1, further comprising a second row of deformed portions below the first row, such that the first row is disposed between the surface and the second row.

4. The substrate as claimed in claim 1, wherein the first row is disposed above a midline of the substrate, the midline being parallel to the surface and half way between the surface and an opposing surface.

5. The substrate as claimed in claim 1, wherein the substrate is a photomask substrate having a lithographic pattern at the surface.

6. The substrate as claimed in claim 5, wherein the lithographic pattern comprises a reflective layer.

7. The substrate as claimed in claim 1, wherein the deformed portions are expanded portions.

8. The substrate as claimed in claim 7, wherein the expanded portions are portions of substrate material having a density lower than that of adjacent unexpanded substrate material.

9. The substrate as claimed in claim 7, wherein the expanded portions are oblong with a longer dimension oriented in a direction substantially normal to the surface and a shorter dimension oriented in the direction substantially parallel to the surface.

10. The substrate as claimed in claim 7, wherein the expanded portions have an average size of greater than or equal to about 1 μm, the size being determined in the direction substantially parallel to the surface.

11. The substrate as claimed in claim 1, wherein the deformed portions in the first row have a pitch of greater than or equal to about 1 μm.

12. A method of adjusting a curvature of a substrate, comprising:
forming at least one deformed portion in a predetermined region of a substrate, wherein:
the substrate comprises a curved region before forming the at least one deformed portion, and
forming the at least one deformed portion comprises irradiating the substrate in the predetermined region so as to fixedly displace substrate material in the predetermined region.

13. The method as claimed in claim 12, wherein forming the at least one deformed portion increases a flatness of a surface of the curved region.

14. The method as claimed in claim 12, wherein a first surface of the substrate has a photomask pattern, and
the curved region is at the first surface.

15. The method as claimed in claim 14, further comprising mapping the substrate to determine the curvature of the substrate, wherein the mapping comprises measuring a surface curvature of the photomask pattern.

16. The method as claimed in claim 12, wherein irradiating the substrate comprises irradiation with a laser.

17. The method as claimed in claim 16, wherein the irradiation is performed with a pulse time of less than or equal to about 1 ms.

18. The method as claimed in claim 16, wherein the irradiation is performed with a pulse energy of less than or equal to about 10 mJ.

19. The method as claimed in claim 12, wherein the at least one deformed portion is formed in a focus location of the laser.

20. The method as claimed in claim 12, wherein displacing the substrate material comprises expanding the substrate material.
